(19) United States
(12) Patent Application Publication
(10) Pub. No.: US 2005/0277066 A1
(43) Pub. Date: Dec. 15, 2005

(54) Selective etch process for step and flash imprint lithography

(76) Inventors: Ngoc V. Le, Gilbert, AZ (US); William J. Dauksher, Mesa, AZ (US); Doug J. Resnick, Gilbert, AZ (US)

Correspondence Address: MOTOROLA, INC., LAW DEPARTMENT, 1303 E. ALGONQUIN ROAD, SCHAUMBURG, IL, 60196, US

(21) Appl. No.: 10/866,563

(22) Filed: Jun. 10, 2004

(51) Int. Cl. G03F 7/00; G03F 7/36

(52) U.S. Cl. 430/316; 430/313

(57) ABSTRACT

A selective etch process for step and flash imprint lithography includes providing (30) a substrate (10); forming (32) a transfer layer (12) on the substrate; forming (34) an etch barrier layer (14) on the transfer layer; patterning (36) the etch barrier layer with a template (16) while curing with ultraviolet light through the template, resulting in a patterned etch barrier layer and a residual layer (20) on the transfer layer; performing (38) an etch to substantially remove the residual layer; and performing (40) an etch with a mixture of nitrogen and hydrogen, and more preferably NH₃, to substantially remove the portion of the transfer layer not underlying the etch barrier layer.

### FIELD OF INVENTION

The present invention relates to semiconductor devices, microelectronic devices, micro electro mechanical devices, microfluidic devices, photonic devices, and more particularly to a method of making these devices using a selective etch process for step and flash imprint lithography.

### BACKGROUND OF THE INVENTION

The fabrication of integrated circuits involves the creation of several layers of materials that interact in some fashion. One or more of these layers may be patterned so various regions of the layer have different electrical characteristics, which may be interconnected within the layer or to other layers to create electrical components and circuits. These regions may be created by selectively introducing or removing various materials. The patterns that define such regions are often created by lithographic processes. For example, a layer of photoresist material is applied onto a layer overlying a wafer substrate. A photomask (containing clear and opaque areas) is used to selectively expose this photoresist material by a form of radiation, such as ultraviolet light, electrons, or x-rays. Either the photoresist material exposed to the radiation, or that not exposed to the radiation, is removed by the application of a developer. An etchant may then be applied to the layer not protected by the remaining resist, and when the resist is removed, the layer overlying the substrate is patterned.

Lithographic processes such as that described above are also typically used to transfer patterns from a photomask to a device. As feature sizes on semiconductor devices decrease into the submicron range, there is a need for new lithographic processes, or techniques, to pattern high-density semiconductor devices. Several new lithographic techniques which accomplish this need and have a basis in imprinting and stamping have been proposed. One in particular, Step and Flash Imprint Lithography has been shown to be capable of patterning lines as small as 20 nm.

Step and Flash Imprint Lithography templates are typically made by applying a layer of chrome, 2-100 nm thick, on to a transparent quartz plate. A resist layer is applied to the chrome and patterned using either an electron beam or optical exposure system. The resist is then placed in a developer to form patterns on the chrome layer. The resist is used as a mask to etch the chrome layer. The chrome then serves as a hard mask for the etching of the quartz plate. Finally, the chrome is removed, thereby forming a quartz template containing relief images in the quartz.

Overall, Step and Flash Imprint Lithography techniques benefit from their unique use of photochemistry, the use of ambient temperatures, and the low pressure required to carry out the Step and Flash Imprint Lithography process. During a typical Step and Flash Imprint Lithography process, a substrate is coated with an organic planarization layer, and brought into close proximity of a transparent Step and Flash Imprint Lithography template, typically comprised of quartz, containing a relief image and coated with a low surface energy material. An ultraviolet or deep ultraviolet sensitive photocurable organic solution is deposited between the template and the coated substrate. Using minimal pressure, the template is brought into contact with the substrate, and more particularly the photocurable organic layer. Next, the organic layer is cured, or crosslinked, at room temperature by illuminating through the template. The light source typically uses ultraviolet radiation. A range of wavelengths (150 nm-500 nm) is possible, depending upon the transmissive properties of the template and photosensitivity of the photocurable organic layer. The template is next separated from the substrate and the organic layer, leaving behind an organic replica of the template relief on the planarization layer. This pattern is then etched with a short halogen break-through, followed by an oxygen reactive ion etch (RIE) to form a high-resolution, high aspect-ratio feature in the organic layer and planarization layer.

Step and Flash Imprint Lithography technology has been demonstrated to resolve features as small as 20 nm. As such, a wide variety of feature sizes may be drawn on a single wafer. Certain problems exist though with this Step and Flash Imprint Lithography pattern transfer methodology as described above. In particular, problems exist with respect to using the oxygen reactive ion etch in the Step and Flash Imprint Lithography process. In Step and Flash Imprint Lithography, an etch barrier layer comprises a formulation having a silicon content of approximately 9%. Generally, the etch barrier layer is selected based upon imprint requirements such as viscosity and mechanical strength and not etch requirements. Therefore, when conventional O₂-based plasma is used for etching the transfer layer, it also etches the etch barrier layer due to the low silicon content, e.g., nine percent or less.

Accordingly, it would be beneficial to provide a means of providing a better method of etching to form high-resolution, high aspect-ratio features in step and flash imprint lithography.

### SUMMARY OF THE INVENTION

A selective etch process for step and flash imprint lithography includes providing a substrate; forming a transfer layer on the substrate; forming an etch barrier layer on the transfer layer; patterning the etch barrier layer with a template while curing with ultraviolet light through the template, resulting in a patterned etch barrier layer and a residual layer on the transfer layer; performing an etch to substantially remove the residual layer; and performing an etch with a mixture of nitrogen and hydrogen, and more preferably with NH₃, to substantially remove the portion of the transfer layer not underlying the etch barrier layer.

Additional advantages of the present invention will be set forth in the Detailed Description which follows and may be obvious from the Detailed Description or may be learned by practice of exemplary embodiments of the invention. Still other advantages of the invention may be realized by means of any of the instrumentalities, methods or combinations particularly pointed out in the claims.

### BRIEF DESCRIPTION OF THE DRAWINGS

Representative elements, operational features, applications and/or advantages of the present invention reside in the details of construction and operation as more fully hereafter depicted, described and claimed—reference being made to the accompanying drawings forming a part hereof, wherein like numerals refer to like parts throughout. Other elements, operational features, applications and/or advantages will become apparent to skilled artisans in light of certain exemplary embodiments recited in the Detailed Description, wherein:

FIG. 1 illustrates layers of material used in a preferred embodiment of the present invention;

FIG. 2 illustrates a template being applied to the layers of material;

FIG. 3 illustrates the material subsequent to a first etch;

FIG. 4 illustrates the material subsequent to an etch using a mixture of hydrogen and nitrogen; and

FIG. 5 illustrates the steps in accordance with the preferred embodiment of the present invention.

Those skilled in the art will appreciate that elements in the Figures are illustrated for simplicity and clarity and have not necessarily been drawn to scale. For example, the dimensions of some of the elements in the Figures may be exaggerated relative to other elements to help improve understanding of various embodiments of the present invention. Furthermore, the terms ‘first’, ‘second’, and the like herein, if any, are used for distinguishing between similar elements and not necessarily for describing a sequential or chronological order. Moreover, the terms front, back, top, bottom, over, under, and the like in the Description and/or in the claims, if any, are generally employed for descriptive purposes and not necessarily for comprehensively describing exclusive relative position. Skilled artisans will therefore understand that any of the preceding terms so used may be interchanged under appropriate circumstances such that various embodiments of the invention described herein, for example, are capable of operation in other orientations than those explicitly illustrated or otherwise described.

### DETAILED DESCRIPTION OF EXEMPLARY EMBODIMENTS

The present invention relates to a selective etch process for step and flash imprint lithography wherein a mixture of nitrogen and hydrogen, and more preferably ammonia (NH₃), is used to etch away a transfer layer resulting in a desired etch resistance to the etch barrier layer with good selectivity.

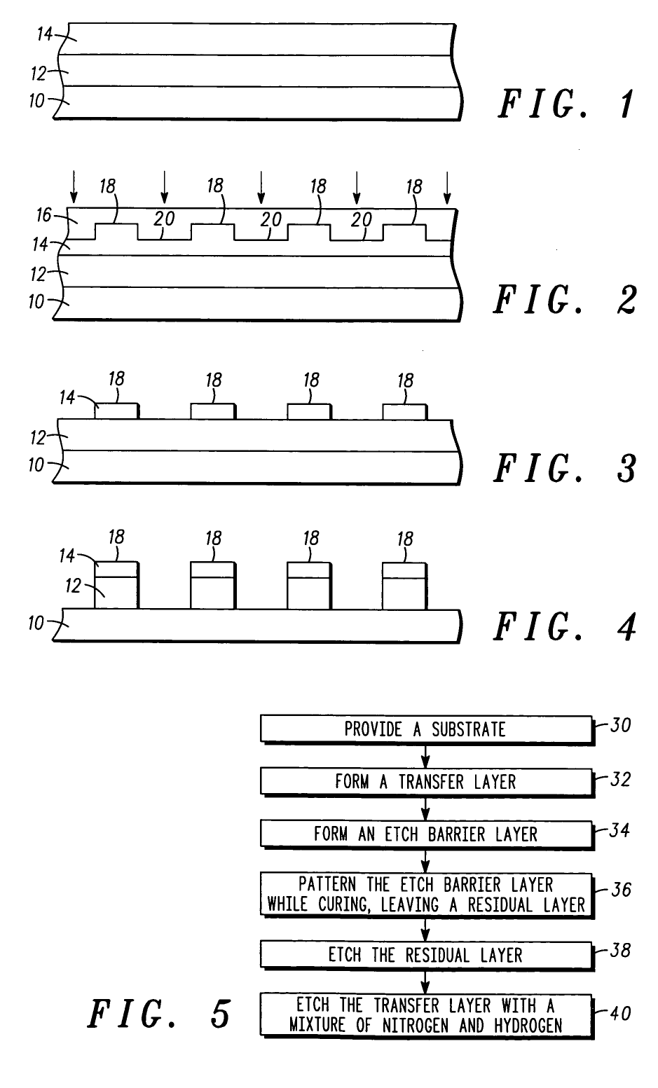

Referring to FIGS. 1-4 for a structure fabricated using an embodiment of the present invention, a transfer layer 12 is spin coated onto the substrate 10 at approximately room temperature and to a thickness between 500 Angstroms to 2 micro meters, but preferably 2000 Angstroms. The transfer layer is an anti-reflective coating that may, for example, comprise Brewer Science DUV30J material. An etch barrier layer 14 photo curable monomer mixture is dispensed in the area to be printed. The etch barrier layer 14 may comprise any number of organic monomer, or mixture of monomers, such as acrylics, ethers, esters, epoxies, or the like for greater etch resistance. The etch barrier layer may also comprise a silicon containing monomer.

Referring to FIG. 2, a transparent template 16 is applied with slight pressure to the etch barrier layer 14 to create the pattern comprising printed features 18 in the etch barrier layer 14. A residual layer 20 comprising the etch barrier layer 14 that was not affected by the application of the template will remain surrounding the printed features 18. The template 16 is fabricated using one of many known methods, and may for example, comprise the template as disclosed in U.S. Pat. No. 6,580,172.

Radiation, such as x-rays or electrons, but more preferably ultra violet light, is transmitted through the transparent template 16 to cure the residual layer 20 and the etch barrier layer 14. The template is then removed. A dry etch, of CF₄/O₂ for example, is performed, removing substantially all the residual layer 20, resulting in the structure as shown in FIG. 3 while also removing some of the etch barrier layer 14.

In accordance with the preferred embodiment of the present invention and referring to FIG. 4, a dry etch using NH₃ (ammonia) is performed to etch away the transfer layer 12 between the printed features 18. In previously known art, an O₂ based plasma, or similar plasma, was used to etch the transfer layer 12. The O₂ based plasma worked fine because the etch barrier layer 14 had a silicon content greater than 19% and was etch resistant to the O₂ based plasma (a silicon oxide-like film is formed which prevents the etch barrier layer from being etched). However, in Step and Flash Imprint Lithography, the etch barrier layer 14 comprises a different formulation having a silicon content of approximately 9%. Generally, the etch barrier layer is selected based upon imprint requirements such as viscosity and mechanical strength and not etch requirements. When an O₂ based plasma is used to etch the transfer layer 12, it also etches the etch barrier layer when it has a low, e.g. 9%, silicon content. However, the use of a nitrogen and hydrogen mixture, and more preferably NH₃, to etch the transfer layer 12 does not substantially etch the etch barrier layer.

The use of NH₃ as an etchant enables a process to pattern transfer sub nanometer features created using the Step and Flash Imprint Lithography. The parameters for the preferred NH₃, as well as a mixture of nitrogen and hydrogen, etch process include the following: bias power between the range of 1 to 1500 Watts, but preferably about 50 Watts; source power between 1 to 1500 Watts, but preferably about 300 Watts; pressure between 1 to 100 milliTorr, but preferably about 15 milliTorr; temperature between −10 to 150 degrees Centigrade (° C.), but preferably about 100° C.; and NH₃ flow between 5 and 1000 standard cubic centimeters per minute, but preferably about 90 standard cubic centimeters per minute.

It should be understood that other gases including N₂ and H₂ mixtures will provide similar results as NH₃. Furthermore, other gases such as N₂, H₂, O₂, CO, CO₂, CHF₃, and Ar may be added to NH₃ to control the critical dimensions of the printed features 18. Gases such as these or others may also be added to control profile. For example, it may be desirable to have an undercut profile such as required for a lift-off process.

Shown in FIG. 5 is a process flow diagram wherein a semiconductor structure, generally illustrated in FIGS. 1-4, is fabricated in accordance with the preferred embodiment of the present invention. Initially, a substrate 10 is provided 30. The transfer layer 12 is then formed 32 on the substrate 10. The etch barrier layer is formed 34 on the transfer layer 12 in accordance with the description given for FIG. 1. The lithographic template 16 is applied with a slight pressure to pattern 36 the etch barrier layer 14. Radiation such as ultra violet light is transmitted through the lithographic template 16 to cure the etch barrier layer 14 and the residual layer formed while the mask is being applied as illustrated in FIG. 2. The template is thereafter removed from the semiconductor device, thereby leaving a patterned layer 18 as illustrated in FIG. 3. The residual layer 20 is then etched 38 and substantially removed. Then, in accordance with the present invention, an etch 40 is performed with NH₃ to provide the structure as illustrated in FIG. 4. It should be understood that although the structure fabricated in accordance with the present invention is described in the preferred embodiment as being used to fabricate a semiconductor device, that anticipated is the formation of other devices including microelectronic devices, micro electro mechanical devices, and microfluidic devices in the remaining structure illustrated in FIG. 4.

In the foregoing specification, the invention has been described with reference to specific exemplary embodiments; however, it will be appreciated that various modifications and changes may be made without departing from the scope of the present invention as set forth in the claims below. The specification and figures are to be regarded in an illustrative manner, rather than a restrictive one and all such modifications are intended to be included within the scope of the present invention. Accordingly, the scope of the invention should be determined by the claims appended hereto and their legal equivalents rather than by merely the examples described above. For example, the steps recited in any method or process claims may be executed in any order and are not limited to the specific order presented in the claims. Additionally, the components and/or elements recited in any apparatus claims may be assembled or otherwise operationally configured in a variety of permutations to produce substantially the same result as the present invention and are accordingly not limited to the specific configuration recited in the claims.

Benefits, other advantages and solutions to problems have been described above with regard to particular embodiments; however, any benefit, advantage, solution to problems or any element that may cause any particular benefit, advantage or solution to occur or to become more pronounced are not to be construed as critical, required or essential features or components of any or all the claims.

As used herein, the terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present invention, in addition to those not specifically recited, may be varied or otherwise particularly adapted by those skilled in the art to specific environments, manufacturing specifications, design parameters or other operating requirements without departing from the general principles of the same.

1. A method for forming a semiconductor device comprising:
providing a substrate;
forming a transfer layer on the substrate;
forming an etch barrier layer on the transfer layer;
patterning the etch barrier layer with a template while curing with radiation through the template, resulting in a patterned etch barrier layer and a residual layer on the transfer layer;
performing an etch to substantially remove the residual layer; and
performing an etch with a mixture nitrogen and hydrogen to substantially remove the portion of the transfer layer not underlying the patterned etch barrier layer.

2. The method for forming a semiconductor device as in claim 1 wherein the performing an etch with the mixture is accomplished with a bias power of between 1 and 1500 Watts.

3. The method for forming a semiconductor device as in claim 1 wherein the performing an etch with the mixture is accomplished with a bias power of approximately 50 Watts.

4. The method for forming a semiconductor device as in claim 1 wherein the performing an etch with the mixture is accomplished with a source power of between 1 and 1500 Watts.

5. The method for forming a semiconductor device as in claim 1 wherein the performing an etch with the mixture is accomplished with a source power of approximately 300 Watts.

6. The method for forming a semiconductor device as in claim 1 wherein the performing an etch with the mixture is accomplished with a pressure of between 1 and 100 milliTorr.

7. The method for forming a semiconductor device as in claim 1 wherein the performing an etch with the mixture is accomplished with a pressure of approximately 15 milliTorr.

8. The method for forming a semiconductor device as in claim 1 wherein the performing an etch with the mixture is accomplished with a temperature of between minus 10 and 150 degrees Centigrade.

9. The method for forming a semiconductor device as in claim 1 wherein the performing an etch with the mixture is accomplished with a temperature of approximately 100 degrees Centigrade.

10. The method for forming a semiconductor device as in claim 1 wherein the performing an etch with the mixture is accomplished with a mixture flow of between 5 and 1000 standard cubic centimeters per minute.

11. The method for forming a semiconductor device as in claim 1 wherein the performing an etch with the mixture is accomplished with a mixture flow of approximately 90 standard cubic centimeters per minute.

12. The method for forming a semiconductor device as in claim 1, further comprising forming semiconductor elements on the substrate.

13. The method for forming a semiconductor device as in claim 1, wherein the etch barrier layer comprises approximately 9% silicon.

14. The method for forming a semiconductor device as in claim 1, wherein the transfer layer is an anti-reflective coating.

15. The method for forming a semiconductor device as in claim 1 wherein the mixture may comprise additional gases.

16. The method for forming a semiconductor device as in claim 15 wherein the additional gases comprise at least one of H₂, O₂, CO, CO₂, CHF₃ and Ar.

17. The method for forming a semiconductor device as in claim 1 wherein the mixture comprises NH₃.

18. The method for forming a semiconductor device as in claim 17, wherein the etch barrier layer comprises approximately 9% silicon.

19. The method for forming a semiconductor device as in claim 17 wherein the mixture may also comprise additional gases.

20. The method for forming a semiconductor device as in claim 19 wherein the additional gases comprise at least one of H₂, O₂, CO, CO₂, CHF₃ and Ar.

21. In a method of forming a device including:
providing a substrate;
forming a transfer layer on the substrate;
forming an etch barrier layer on the transfer layer;
patterning the etch barrier layer with a template while curing with radiation through the template, resulting in a patterned etch barrier layer and a residual layer on the transfer layer;
performing an etch to substantially remove the residual layer; the improvement comprising:
performing an etch with a mixture of N₂ and H₂ to substantially remove the portion of the transfer layer not underlying the patterned etch barrier layer.

22. The method for forming a device as in claim 21 wherein the performing an etch with a mixture of N₂ and H₂ is accomplished with a bias power of between 1 and 1500 Watts.

23. The method for forming a device as in claim 21 wherein the performing an etch with a mixture of N₂ and H₂ is accomplished with a bias power of approximately 50 Watts.

24. The method for forming a device as in claim 21 wherein the performing an etch with a mixture of N₂ and H₂ is accomplished with a source power of between 1 and 1500 Watts.

25. The method for forming a device as in claim 21 wherein the performing an etch with a mixture of N₂ and H₂ is accomplished with a source power of approximately 300 Watts.

26. The method for forming a device as in claim 21 wherein the performing an etch with a mixture of N₂ and H₂ is accomplished with a pressure of between 1 and 100 milliTorr.

27. The method for forming a device as in claim 21 wherein the performing an etch with a mixture of N₂ and H₂ is accomplished with a pressure of approximately 15 milliTorr.

28. The method for forming a device as in claim 21 wherein the performing an etch with a mixture of N₂ and H₂ is accomplished with a temperature of between minus 10 and 150 degrees Centigrade.

29. The method for forming a device as in claim 21 wherein the performing an etch with a mixture of N₂ and H₂ is accomplished with a temperature of approximately 100 degrees Centigrade.

30. The method for forming a device as in claim 21 wherein the performing an etch with a mixture of N₂ and H₂ is accomplished with a mixture flow of between 5 and 1000 standard cubic centimeters per minute.

31. The method for forming a device as in claim 21 wherein the performing an etch with a mixture of N₂ and H₂ is accomplished with a mixture flow of approximately 90 standard cubic centimeters per minute.

32. The method for forming a device as in claim 21 wherein the device is one of a microelectronic device, a micro electro mechanical device, a microfluidic device, and a semiconductor device.

33. The method for forming a device as in claim 21 wherein the etch barrier layer comprises approximately 9% silicon.

34. The method for forming a device as in claim 21 wherein the transfer layer is an anti-reflective coating.

35. The method for forming a device as in claim 21 wherein the mixture may comprise additional gases.

36. The method for forming a device as in claim 35 wherein the additional gases comprise at least one of H₂, O₂, CO, CO₂, CHF₃ and Ar.

37. The method for forming a device as in claim 21 wherein the mixture comprises NH₃.

38. The method for forming a device as in claim 37 wherein the etch barrier layer comprises approximately 9% silicon.

39. The method for forming a device as in claim 37 wherein the mixture may comprise additional gases.

40. The method for forming a device as in claim 39 wherein the additional gases comprise at least one of H₂, O₂, CO, CO₂, CHF₃ and Ar.
